(19) United States
(12) Patent Application Publication
(10) Pub. No.: US 2009/0176367 A1
(43) Pub. Date: Jul. 9, 2009

(54) OPTIMIZED SiCN CAPPING LAYER

(76) Inventors: Heidi Baks, Poughkeepsie, NY (US); James T. Kelliher, Manassas, VA (US); Huang Liu, Singapore (SG)

Correspondence Address: Intellectual Property Law;IBM Corporation, Dept. 18G, Building 300-482, 2070 Route 52, Hopewell Junction, NY, 12533, US

(21) Appl. No.: 11/970,748

(22) Filed: Jan. 8, 2008

(51) Int. Cl. H01L 21/768

(52) U.S. Cl. 438/654; 257/E21.584

(57) ABSTRACT

A back-end-of-line (BEOL) interconnect structure and a method of forming an interconnect structure. The interconnect structure comprises a conductor, such as copper, embedded in a dielectric layer, and a low-k dielectric capping layer, which acts as a diffusion barrier, on the conductor. A method of forming the BEOL interconnect structure is disclosed, where the capping layer is deposited using plasma-enhanced chemical vapor deposition (PECVD) and is comprised of Si, C, H, and N. The interconnect structure provides improved oxygen diffusion resistance and improved barrier qualities allowing for a reduction in film thickness.

This application claims the benefits of pending U.S. patent application Ser. No. 11/164,419 filed on Nov. 22, 2005.

### BACKGROUND OF THE INVENTION

1. Field of the Invention

This invention generally relates to the manufacture of high speed semiconductor microprocessors, application specific integrated circuits (ASICs), and other high speed integrated circuit devices. More specifically, the invention relates to advanced fabrication schemes for semiconductor devices that include a cap layer having a low-k dielectric constant and comprised of an amorphous hydrogenated silicon carbide (Si—C—H) material.

2. Background Art

Metal interconnections in very large scale integrated (VLSI) or ultra-large scale integrated (ULSI) circuits typically consist of interconnect structures containing patterned layers of metal wiring. Typical integrated circuit (IC) devices contain from three to fifteen layers of metal wiring. As feature size decreases and device density increases, the number of interconnect layers is expected to increase.

The materials and layout of these interconnect structures are preferably chosen to minimize signal propagation delays, hence maximizing the overall circuit speed. An indication of signal propagation delay within the interconnect structure is the RC time constant for each metal wiring layer, where R is the resistance of the wiring and C is the effective capacitance between a selected signal line (i.e., conductor) and the surrounding conductors in the multilevel interconnect structure. The RC time constant may be reduced by lowering the resistance of the wiring material. Copper is therefore a preferred material for IC interconnects because of its relatively low resistance. The RC time constant may also be reduced by using dielectric materials with a lower dielectric constant, k.

State-of-the-art dual damascene interconnect structures comprising a low-k dielectric material and copper interconnects are described in “Reliability, Yield, and Performance of a 90 nm SOI/Cu/SiCOH Technology,” by D. Edelstein el al., Proceedings of the IEEE 2004 International Interconnect Technology Conference, pp. 214-216. A typical interconnect structure using a low-k dielectric material and copper interconnects is shown in FIG. 1. The interconnect structure comprises a lower substrate 10 which may contain logic circuit elements such as transistors. A dielectric layer 12, commonly known as an interlayer dielectric (ILD), overlies the substrate 10. An adhesion promoter layer 11 may be disposed between the substrate 10 and ILD layer 12. A hardmask layer 13 may be disposed on ILD layer 12. This hardmask layer 13 is typically composed of silicon nitride, but may also be comprised of silicon oxide or silicon carbide. The hardmask layer 13 may function as a patterning layer to assist in later etching of ILD layer 12, and it may also serve as a polish stop layer during a subsequent chemical-mechanical polish (CMP) step to remove excess metal.

At least one conductor 15 is embedded in ILD layer 12. Conductor 15 is typically copper in advanced interconnect structures, but may alternatively be aluminum or other conductive material. A diffusion barrier liner 14 may be disposed between ILD layer 12 and conductor 15. Diffusion barrier liner 14 is typically comprised of tantalum, titanium, tungsten or nitrides of these metals. The top surface of conductor 15 is made coplanar with the top surface of hardmask layer 13 usually by a chemical-mechanical polish (CMP) step. A cap layer 16, also typically of silicon nitride, is disposed on conductor 15 and hardmask layer 13. The cap layer may also be comprised of silicon carbide or silicon dioxide. Cap layer 16 acts as a diffusion barrier to prevent diffusion of copper from conductor 15 into the surrounding dielectric material. The cap layer 16 also protects the copper against oxidation during further processing.

A first interconnect level is defined by adhesion promoter layer 11, ILD layer 12, hardmask layer 13, diffusion barrier liner 14, conductor 15, and cap layer 16 in the interconnect structure shown in FIG. 1. A second interconnect level, shown above the first interconnect level in FIG. 1, includes adhesion promoter layer 17, ILD layer 18, hardmask layer 19, diffusion barrier liner 20, conductor 21, and cap layer 22. Interconnect lines in each interconnect level and vias connecting level to level may be formed by conventional single or dual damascene processes, as known to those skilled in the art.

Formation of the second interconnect level begins with deposition of adhesion promoter layer 17. Next, the ILD material 18 is deposited onto adhesion promoter layer 17. The ILD material 18 can be deposited by plasma-enhanced chemical vapor deposition (PECVD) or by spin application. Examples of PECVD ILDs include fluorine-doped and carbon-doped silicon oxides, and an example of spin-on ILDs is a polymeric thermoset material such as SiLK™. Next, hardmask layer 19 is deposited on the ILD. The chosen ILD and integration scheme dictates whether adhesion and hardmask layers are used and of what type of materials these layers are comprised. Hardmask layer 19, ILD layer 18, adhesion promoter layer 17 and cap layer 16 are then patterned, using a conventional photolithography and etching process, to form at least one trench and via. The trenches and vias are typically lined with diffusion barrier liner 20. The trenches and vias are then filled with a metal such as copper to form conductor 21 in a conventional dual damascene process. Excess metal is removed by a CMP process. Finally, cap layer 22 is deposited on copper conductor 21 and hardmask layer 19.

Focusing on the cap material, silicon nitride has a relatively high dielectric constant of about 6 to 7. Fringing electric fields between the copper conductors are known to be present in regions of the copper where a higher-k cap/diffusion barrier film such as silicon nitride is present. When a material having a low dielectric constant of about 2 to 3 is used for the ILD, the effective capacitance of the metal conductors is increased by using a higher-k silicon nitride cap/diffusion barrier layer, resulting in decreased overall interconnect speed. The effective capacitance is also increased by using a higher-k silicon nitride polish-stop layer.

An alternative material for cap layers 16 and 22 is an amorphous hydrogenated silicon carbide material (SiₓC_{y}H_{z}), one example being the material known as Blok™. (an amorphous film composed of silicon, carbon and hydrogen, which is available from Applied Materials, Inc.). SiₓC_{y}H_{z} has a dielectric constant of less than 5, which is lower than that of silicon nitride. Thus, in an interconnect structure using SiₓC_{y}H_{z} for the cap layer, the effective capacitance of the metal conductors is decreased, and the overall interconnect speed is increased.

It has been discovered, however, that Si—C—H is not a good oxygen barrier, which leads to relatively high electromigration rates. These high electromigration rates adversely affect the reliability of the IC chip.

As another alternative, nitrogen can be added to the Si—C—H material, forming an amorphous nitrogenated hydrogenated silicon carbide material (Si—C—N—H). While, under certain circumstances, Si—C—N—H is a better oxygen barrier than Si—C—H, Si—C—N—H still does not have the desired oxygen barrier properties possessed by silicon nitride. Also, Si—C—N—H, under most conventional semiconductor manufacturing conditions, has a slightly higher dielectric constant than Si—C—H. Under typical semiconductor manufacturing conditions, Si—C—H has a dielectric constant of 4.5 and Si—C—N—H has a dielectric constant of 5.0-5.5. Oxygen barrier properties of Si—C—N—H may be improved by increasing the deposition temperature, however, this leads to an even higher dielectric constant for the capping layer. For example, when the deposition temperature was increased from 350° C. to 400° C., the dielectric constant increased from 5.0 to 5.5. In addition, a higher deposition temperature may cause hillock formation in the copper metallization, which could cause an interlevel short.

Thus, while the use of Si—C—H and Si—C—N—H materials as capping layers has some advantages, there is still a need in the art for an interconnect structure utilizing copper or aluminum conductors, a low-k ILD having a dielectric constant of about 2 to 3, and a cap layer which has optimum barrier properties while minimizing its dielectric constant.

### SUMMARY OF THE INVENTION

An object of this invention is to provide an improved semiconductor interconnect structure.

Another object of the invention is to provide an interconnect structure having a cap layer that has a dielectric constant of about 5.0 to 5.5 and that also provides effective oxygen barrier properties. This is achieved by optimizing the density of the cap film.

These and other objectives are attained with an interconnect structure and a method of forming an interconnect structure. The interconnect structure comprises a conductor, such as copper, embedded in a dielectric layer; and a low-k dielectric capping layer on the conductor, the capping layer comprising Si, C, H and optionally N.

Further benefits and advantages of the invention will become apparent from a consideration of the following detailed description, given with reference to the accompanying drawings, which specify and show preferred embodiments of the invention.

### BRIEF DESCRIPTION OF THE DRAWINGS

FIG. 1 is a schematic cross-sectional view of a partially-fabricated integrated circuit device illustrating a prior art interconnect structure.

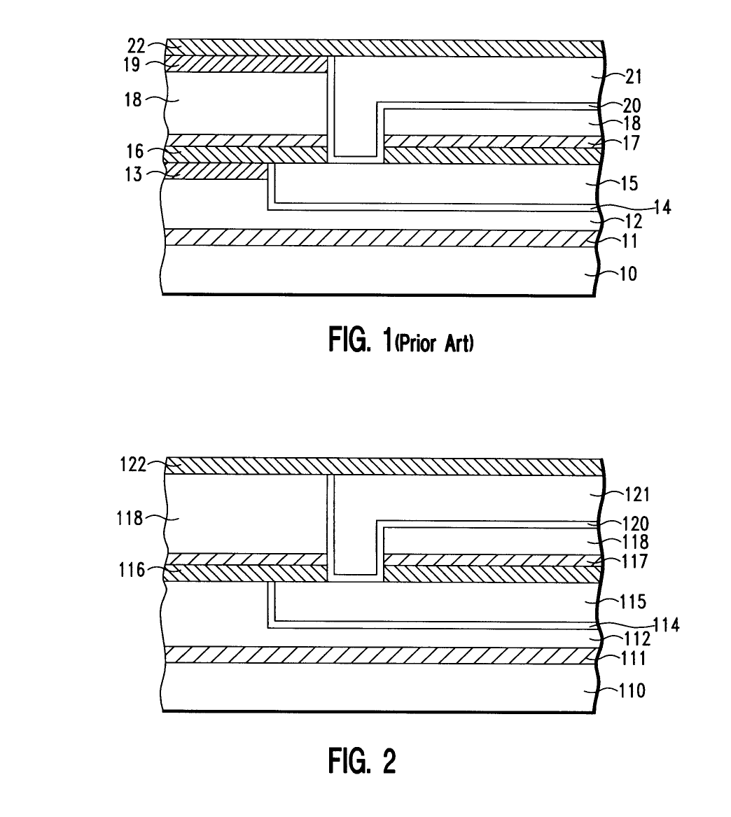

FIG. 2 is a schematic cross-sectional view of a partially-fabricated integrated circuit device illustrating an interconnect structure in accordance with a preferred embodiment of this invention.

FIGS. 3(a)-3(i) show a preferred method for forming the interconnect structure of FIG. 2.

FIG. 4 is the elemental Auger depth profile of an air annealed 350° C. Si—C—N—H film with density consistent with prior art, illustrating oxygen penetration through the film to the underlying Cu.

FIG. 5 is an elemental Auger depth profile of an air annealed 400° C. Si—C—N—H film, which has increased film density compared to the film in FIG. 4, illustrating oxygen penetration into 50% of the film thickness. This indicates improve barrier film property against oxygen, preventing oxygen from reaching the underlying Cu.

FIG. 6 is an elemental Auger depth profile of an air annealed improved 350° C. Si—C—N—H film, which has similar film density of the film in FIG. 5, illustrating equivalent oxygen barrier performance to the film in FIG. 5.

FIG. 7 shows a significant reduction in hillocks for the improved 350° C. film compared to the 400° C. film, as detected by defect density using darkfield wafer inspection post ILD deposition and etch at the next processing level. The inset show a top-down SEM image of the hillock defect, covered by ILD deposition at the next level, directly over Cu lines on the previous level.

### DETAILED DESCRIPTION OF THE PREFERRED EMBODIMENTS

The invention will now be described by reference to the accompanying figures. In the figures, various aspects of the structures have been shown and schematically represented in a simplified manner to more clearly describe and illustrate the invention. For example, the figures are not intended to be to scale. In addition, the vertical cross-sections of the various aspects of the structures are illustrated as being rectangular in shape. Those skilled in the art will appreciate, however, that with practical structures, these aspects will most likely incorporate more tapered features. Moreover, the invention is not limited to constructions of any particular shape.

Although certain aspects of the invention will be described with respect to a structure comprising copper, the invention is not so limited. Although copper is the preferred conductive material, the structure of the present invention may comprise any suitable conductive material, such as aluminum.

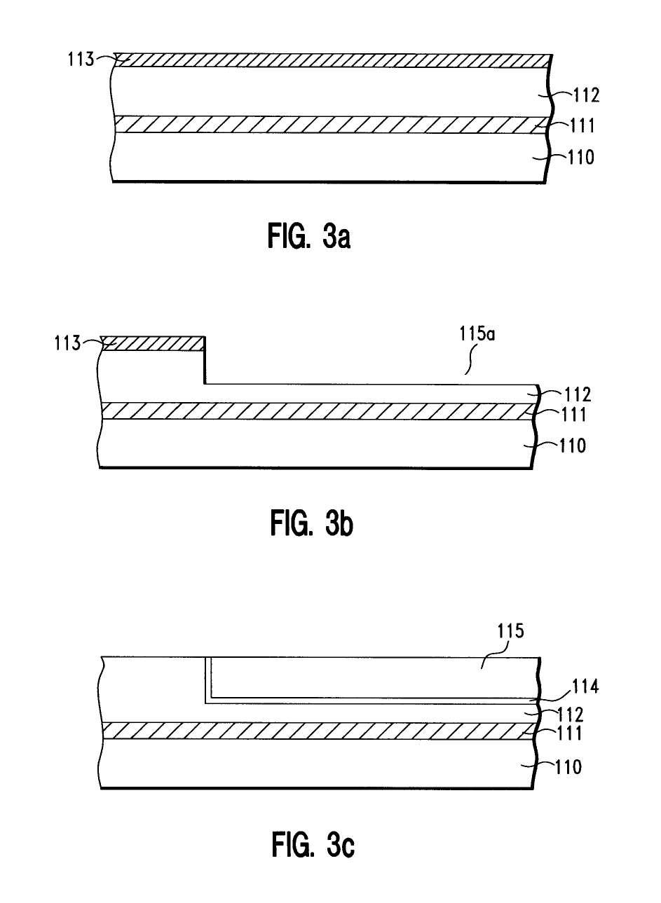

Referring to FIG. 2, a preferred embodiment of the interconnect structure of this invention comprises a lower substrate 110 which may contain logic circuit elements such as transistors. A dielectric layer 112, commonly known as an interlayer dielectric (ILD), overlies the substrate 110. An adhesion promoter layer 111 may be disposed between substrate 110 and ILD layer 112. At least one conductor 115 is embedded in ILD layer 112. A diffusion barrier liner 114 may be disposed between ILD layer 112 and conductor 115. The top surface of conductor 115 is made coplanar with the top surface of ILD layer 112, usually by a chemical-mechanical polish (CMP) step. A cap layer 116 is disposed on conductor 115.

A first interconnect level is defined by adhesion promoter layer 111, ILD layer 112, diffusion barrier liner 114, conductor 115, and cap layer 116 in the interconnect structure shown in FIG. 2. A second interconnect level, shown above the first interconnect level in FIG. 2, includes adhesion promoter layer 117, ILD layer 118, diffusion barrier liner 120, conductor 121, and cap layer 122.

ILD layers 112 and 118 may be formed of any suitable dielectric material, although low-k dielectric materials are preferred. Suitable dielectric materials include carbon-doped silicon dioxide (also known as silicon oxycarbide or SiCOH dielectrics); fluorine-doped silicon oxide (also known as fluorosilicate glass, or FSG); spin-on glasses; silsesquioxanes, including hydrogen silsesquioxane (HSQ), methyl silsesquioxane (MSQ) and mixtures or copolymers of HSQ and MSQ; and any silicon-containing low-k dielectric. Examples of spin-on low-k films with SiCOH-type composition using silsesquioxane chemistry include HOSP™ (available from Honeywell), JSR 5109 and 5108 (available from Japan Synthetic Rubber), Zirkon™ (available from Shipley Microelectronics), and porous low-k (ELk) materials (available from Applied Materials). Spin-on low-k films with organic composition are polymeric thermoset materials, consisting essentially of carbon, oxygen and hydrogen. Preferred organic dielectric materials include the low-k polyarylene ether polymeric material known as SiLK™ (available from The Dow Chemical Company), and the low-k polymeric material known as FLARE (available from Honeywell).

For this embodiment, the preferred dielectric material is carbon-doped silicon oxide (SiCOH), deposited by PECVD. For this particular ILD, an in-situ adhesion layer (also called transition layer) is used. A sacrificial hardmask is deposited on top of the ILD material (not shown in FIG. 2) to aid in RIE patterning and to protect the ILD material during processing; this sacrificial hardmask is removed during CMP planarization. ILD layers 112 and 118 may each be about 100 nm to about 1000 nm thick, but these layers are each preferably about 600 nm thick. The dielectric constant for ILD layers 112 and 118 is preferably about 1.8 to about 3.5, and most preferably about 2.5 to about 2.9.

Alternatively, ILD layers 112 and 118 may be formed of a material with either silsesquioxane-type composition, or an organic polymeric thermoset material, containing pores. If ILD layers 112 and 118 are formed of such porous dielectric material, the dielectric constant of these layers is preferably less than about 2.6, and is most preferably about 1.5 to 2.5. It is particularly preferred to use a porous dielectric material having a dielectric constant of about 1.8 to 2.2.

The choice of adhesion promoters depend on the particular ILD material chosen. In U.S. Patent Application Publication 20050059258, a thin PECVD-deposited transition layer is used for SiCOH ILD. The transition layer, represented by layers 111 and 117 in FIG. 2, is formed while the plasma of the surface pretreatment step is still present and active in the reactor chamber at the same time the precursors of the film that is being deposited are introduced into the reactor chamber. In this case, siloxane or other oxygen-bearing organosilicon precursors are used, resulting in a transition layer thickness of 5-20 nm.

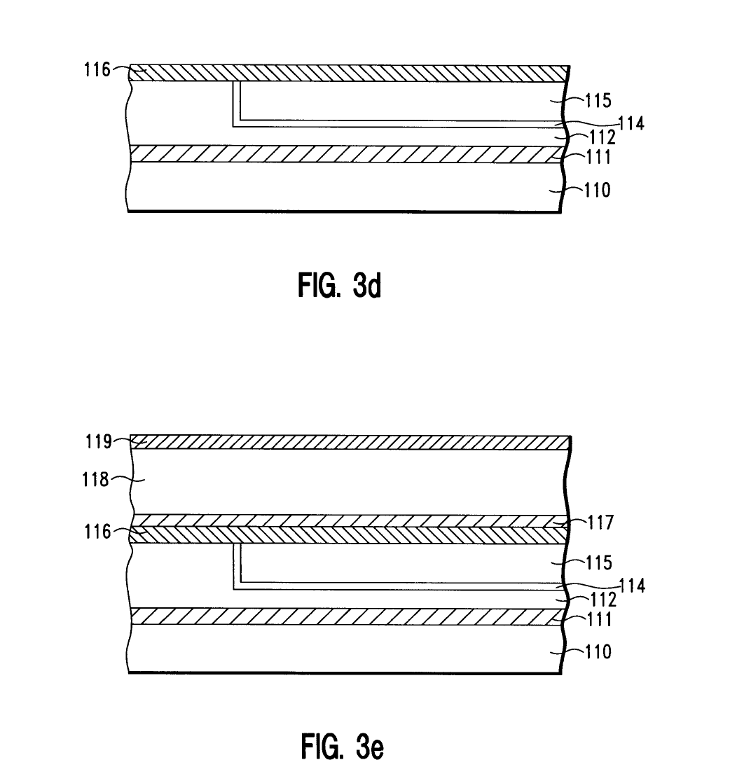

This embodiment uses sacrificial hardmask layers 113 and 119 (described later accompanying FIG. 3) to aid in RIE patterning and protection of the ILD material during RIE processing. The hardmask material chosen depends on the ILD choice, and can be any of the following or multiple layers thereof: silicon oxide, silicon nitride, silicon oxynitride, silicon carbide, nitrogenated silicon carbide, silicon carbo-oxide, or modified SiCOH. Hardmask layers 113 and 119 should be in strong adhesive contact with ILD layers 112 and 118, respectively. Hardmask layers 113 and 119 are preferably in the range of about 20 to about 100 nm thick, and most preferably in the range of about 25 to about 70 nm thick.

Although we describe the use of an adhesion layer and sacrificial hardmask layer for preferred ILD SiCOH, the invention is not so limited to that particular integration scheme. Use of and choice of material for adhesion and hardmask layers are dictated by the choice of ILD and appropriate integration scheme for that ILD, and the spirit of this invention is maintained whether either the adhesion layer or hardmask layer(s) are utilized or not.

Conductors 115 and 121 may be formed of any suitable conductive material, such as copper or aluminum. Copper is particularly preferred as the conductive material, due to its relatively low resistance. Copper conductors 115 and 121 may contain small concentrations of other elements. Diffusion barrier liners 114 and 120 may comprise one or more of the following materials: tantalum, titanium, tungsten and the nitrides of these metals. Cap layers 116 and 122 are preferably formed of an amorphous nitrogenated hydrogenated silicon carbide material (Si—C—N—H) comprising silicon, carbon, nitrogen, and hydrogen.

More specifically, these cap layers are preferably composed of about 20 to 34 atomic % silicon, about 12 to 34 atomic % carbon, about 5 to 30 atomic % nitrogen, and about 20 to 50 atomic % hydrogen. In other words, cap layers 116 and 122 preferably have the composition SiₓC_{y}N_{w}H_{z}, where x is about 0.2 to about 0.34, y is about 0.12 to about 0.34, w is about 0.05 to about 0.3, and z is about 0.2 to about 0.5.

A particularly preferred composition for cap layers 116 and 122 is about 22 to 30 atomic % silicon, about 15 to 30 atomic % carbon, about 10 to 25 atomic % nitrogen, and about 30 to 45 atomic % hydrogen. This particularly preferred composition may be expressed as SiₓC_{y}N_{w}H_{z}, where x is about 2.2 to about 3, y is about 1.5 to about 3, w is about 1 to about 2.5, and z is about 3 to about 4.5. Cap layers 116 and 122 should be in strong adhesive contact with conductors 115 and 121 and ILD layers 112 and 118, respectively. Cap layers 116 and 122 are preferably in the range of about 5 to about 120 nm thick, and most preferably in the range of about 20 to about 70 nm thick.

The cap layers of this invention, such as cap layers 116 and 122 provide an improved barrier to copper atoms or ions migrating out of the copper conductors, and also provide an improved barrier to diffusion of oxygen species (such as O₂ and H₂) moving into the conductor. The latter oxidizing species are believed to be a principal source of failure of interconnect structures under accelerated stress conditions.

At the interface between the cap layer and the conductor, such as between cap layer 116 and conductor 115, the cap layer preferably contains less than about 1 atomic % oxygen. The oxygen concentration at this interface may be measured, for example, by Auger Electron Spectroscopy (AES) or by electron energy loss spectroscopy in a Transmission Electron Microscope (TEM). The reliability of the interconnect structure under accelerated stress conditions can be significantly improved by maintaining the oxygen content at this interface at less than about 1 atomic %. This can be achieved by subjecting the surface of the conductor to an ammonia plasma pre-clean step, which is described in more detail below.

Alternatively, the cap layer may contain a higher nitrogen concentration at the interface between the cap layer and the conductor, such as between cap layer 116 and conductor 115, than is present in the remainder of the cap layer. In other words, the bottom surface of the cap layer, which is that surface in contact with the conductor, may be enriched with nitrogen as compared to the bulk of the cap layer. The preferred nitrogen concentration at this interface is in the range of about 5 to 20 atomic %, more preferably in the range of about 10 to 15 atomic %. Nitrogen enrichment at this interface results from the ammonia plasma pre-clean step, which is described in more detail below. Nitrogen concentration at the interface may be measured by Auger electron spectroscopy (AES) depth profile, with the signal being calibrated by Rutherford backscattering spectroscopy (RBS).

The interconnect structure of FIG. 2 may be formed by a single or dual damascene process, such as the process shown in FIGS. 3(a)-3(i). The process preferably begins with deposition of adhesion promoter layer 111 on substrate 110, and is followed by deposition of ILD layer 112 on adhesion promoter layer 111, as shown in FIG. 3(a). Adhesion promoter layer 111 and ILD layer 112 may be deposited by any suitable method, depending on ILD used.

Sacrificial hardmask layer 113 is then deposited on ILD layer 112, as shown in FIG. 3(a). Sacrificial hardmask layers may be deposited by any suitable method, but is preferably deposited by plasma enhanced chemical vapor deposition (PECVD) directly onto ILD layer 112.

In FIG. 3(b), at least one trench 115a is formed using a conventional photolithography patterning and etching process. In a typical photolithography process, a photoresist material (not shown) is deposited on sacrificial hardmask layer 113. The photolithography material is exposed to ultraviolet (UV) radiation through a mask, and then the photoresist material is developed. Depending on the type of photoresist material used, exposed portions of the photoresist may be rendered either soluble or insoluble during development. These soluble portions of the photoresist are then removed, leaving behind a photoresist pattern matching the desired pattern of trenches. Trench 115a is then formed by removing sacrificial hardmask layer 113 and a portion of ILD layer 112 by, for example, reactive ion etching (RIE), in areas not protected by the photoresist. Sacrificial hardmask layer 113 may assist in this etching step as follows. Sacrificial hardmask layer 113 may be etched first in areas not covered by the photoresist, then the photoresist may be removed, leaving behind a patterned sacrificial hardmask layer 113 matching the photoresist pattern. Then, ILD layer 112 may be etched in areas not covered by sacrificial hardmask layer 113.

With reference to FIG. 3(c), after formation of trench 115a, the trench is preferably lined with diffusion barrier liner 114, and then a conductive material is deposited in trench 115a to form conductor 115. Diffusion barrier liner 114 may be deposited by any suitable method, such as by physical vapor deposition (PVD) or “sputtering,” or by chemical vapor deposition (CVD). A preferred method for depositing diffusion barrier liner 114 is ionized PVD. The diffusion barrier liner may be a multilayer of metals and metal nitrides deposited by PVD and/or CVD. Conductive material 115 may be deposited in trench 115a by any suitable method, such as by electroplating, PVD or CVD. Electroplating is the most preferred method for depositing copper conductive material 115. Excess liner 114, conductive material 115 and sacrificial hardmask 113 is removed in a CMP process, in which the top surface of conductor 115 is made coplanar with ILD layer 112.

Prior to deposition of cap layer 116, a plasma cleaning step is preferably performed in the PECVD reactor. For a 200 mm PECVD reactor, a typical plasma cleaning step uses a source of hydrogen such as NH₃ or H₂ at a flow rate in the range of about 50 to 500 sccm, and is performed at a substrate temperature in the range of about 150° C. to 500° C., most preferably at a substrate temperature in the range of about 300° C. to 400° C., for a time of about 5 to 500 seconds and most preferably about 10 to 100 seconds. The RF power is in the range of about 100 to 700 watts, and most preferably in the range of about 200 to 500 watts during this cleaning step. Optionally, other gases such as He, argon (Ar) or N₂ may be added at a flow rate in the range of about 50 to 500 sccm. For a 300 mm PECVD reactor, the preferred NH₃ or H₂ flow rate is in the range of 500-2000 sccm, other optional gases such as He, Ar, or N₂ is in the range of 500-2000 sccm, and the RF power is in the range of 200-800 watts.

Cap layer 116 is then deposited on conductor 115 and ILD layer 112, as shown in FIG. 3(d). Cap layer 116 is preferably deposited using a PECVD process, in a reactor at a pressure in the range of about 0.1 to 20 torr, most preferably in a range of about 1 to about 10 torr, using a combination of gases that may include, but are not limited to, SiH₄, NH₃, N₂, He, 3 MS, 4 MS, and other methyl silanes.

Cap layer 116 is preferably deposited using 3 MS or 4 MS at a flow rate in the range of about 50 to 500 sccm and He at a flow rate in the range of about 50 to 2000 sccm. The deposition temperature is preferably in the range of about 150° C. to 500° C., and most preferably in the range of about 300° C. to 400° C. Nitrogen is incorporated into the film by either N₂ or NH₃ gas. For a 200 mm PECVD reactor, the N₂ or NH₃ flow rate is in the range of about 50 to 500 sccm, and the RF power is preferably in the range of about 100 to 700 watts, and most preferably in the range of about 200 to 500 watts. For a 300 mm PECVD reactor, the N₂ or NH₃ flow rate is in the range of about 800 to 2000 sccm, and the RF power is most preferably in the range of about 400 to 800 watts. The final deposition thickness is preferably in the range of about 10 to 100 nm, and most preferably in the range of about 25 to 70 nm.

FIGS. 3(a)-3(d) illustrate the formation of the first interconnect level, which is comprised of adhesion promoter layer 111, ILD layer 112, diffusion barrier liner 114, conductor 115 and cap layer 116. In FIG. 3(e), the formation of the second interconnect level begins with deposition of adhesion promoter layer 117, ILD layer 118 and sacrificial hardmask layer 119. Adhesion promoter layer 117 may be deposited using the same method as that for adhesion promoter layer 111. Likewise, ILD layer 118 may be deposited using the same method as that for ILD layer 112, and sacrificial hardmask layer 119 may be deposited using the same method as that for sacrificial hardmask layer 113.

FIGS. 3(f) and 3(g) illustrate the formation of via 121a and trench 121b. First, at least one via 121a may be formed in sacrificial hardmask layer 119, ILD layer 118, adhesion promoter layer 117 and cap layer 116, using a conventional photolithography patterning and etching process, as shown in FIG. 3(f). Then, at least one trench 121b may be formed in sacrificial hardmask layer 119 and a portion of ILD layer 118, using a conventional photolithography process, as shown in FIG. 3(g). Via 121a and trench 121b may be formed using the same photolithography process as that used to form trench 115a.

Alternatively, via 121a and trench 121b may be formed by first patterning and etching a trench in sacrificial hardmask 119 and ILD layer 118, where the trench has a depth equal to the depth of trench 121b but has a length equal to the length of trench 121b and the width of via 121a combined. Then via 121a may be formed by etching through the remainder of ILD layer 118, adhesion promoter layer 117 and cap layer 116.

As shown in FIG. 3(h), after formation of via 121a and trench 121b, the via and trench are preferably lined with diffusion barrier liner 120, and then a conductive material is deposited in the via and trench to form conductor 121. Diffusion barrier liner 120 may be deposited by the same method used for diffusion barrier liner 114, and conductive material 121 may be deposited by the same method used for conductor 115. Excess liner 120, conductive material 121 and sacrificial hardmask 119 are removed in a CMP process, in which the top surface of conductor 121 is made coplanar with ILD layer 118.

Cap layer 122 is then deposited on conductor 121 and ILD layer 118, as shown in FIG. 3(i). Cap layer 122 may be deposited using the same PECVD process as that for cap layer 116.

The following non-limiting examples are provided so that one skilled in the art may more readily understand the invention.

### EXAMPLE 1

When utilizing a 300 mm PECVD reactor, the optimized process ranges have been listed previously and are summarized here.

| | |
|---|---|
| Processing condition | 300 mm PECVD reactor |
| Temperature | 300-400° C. |
| RF Power | 400-800 W |
| 3MS or 4MS flow rate | 50-500 sccm |
| He flow rate | 50-2000 sccm |
| N₂ or NH₃ flow rate | 800-2000 sccm |

For deposition temperature of 400° C., the specific conditions are 3 MS flow of 450 sccm, NH₃ flow of 1740 sccm, He flow of 730 sccm, and RF plasma power of 480 watts. The higher deposition temperature leads to a film with higher density, 2.10 g/cm³ by X-ray reflectance (XRR) as compared to 1.97 g/cm³ for the 200 mm PECVD reactor film described in U.S. Patent Application Publication 20030134495, and with a higher dielectric constant of 5.5. Although this is a compromise of dielectric constant, the higher film density leads to better barrier properties to both oxygen and copper species. Another benefit of an increased density in capping layer is that it is a good etch stop for via first processing. Improved density also allows for the barrier film thickness to be reduced in future semiconductor generations, as less film thickness is needed to stop diffusing species from migrating through the film into the ILD or metal lines.

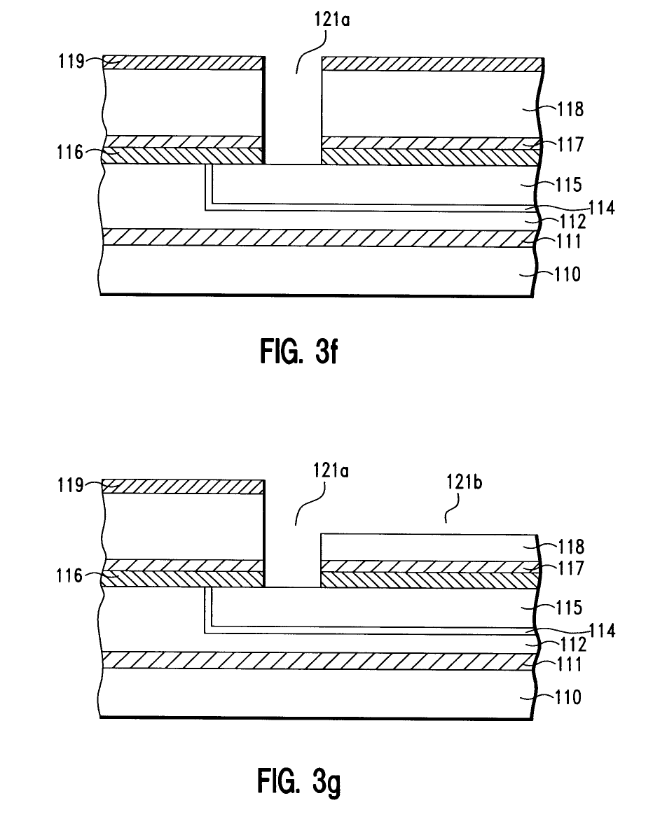

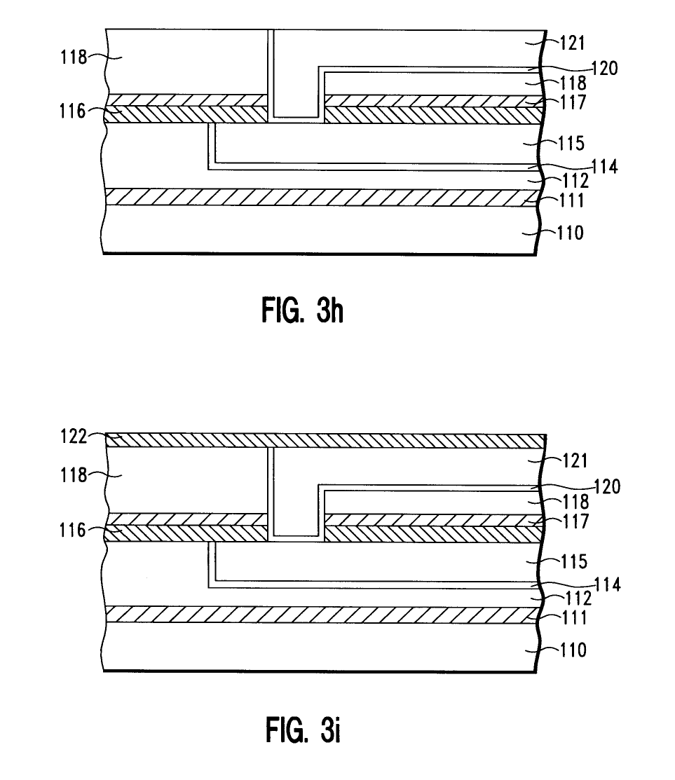

The improved barrier quality is illustrated in FIGS. 4 and 5, which show the concentrations of several elements as a function of depth, in two Si—C—N—H layers after a furnace anneal in air. This analysis is performed by annealing the sample in air at 310-320° C. for about 10-24 hours in order to check whether a capping layer is a good oxygen barrier, followed by Auger Electron Spectroscopy (AES) depth profiling. Since the air contains oxygen, high temperature annealing would cause oxygen to diffuse through the capping layer, if the capping layer is not a good oxygen barrier. This experiment simulates the process condition where, during the FTEOS deposition or CVD low-k deposition, the wafer is in the oxygen environment at a high temperature. FIG. 4 is a 300 mm Si—C—N—H sample, deposited onto a thick layer of Cu on a liner/Si substrate, with film density similar to the 200 mm film in U.S. Patent Application Publication 20030134495. The depth of 0 nm on the left of the x-axis represents the cap surface, and moving right on the x-axis represents vertical depth into the film until the thick Cu layer is reached. FIG. 5 is the depth profile of the 300 mm 400° C. sample after air annealing. As a comparison of these figures illustrates, the improved film density substantially improves the resistance of Si—C—N—H to oxygen diffusion.

From an Auger Electron Spectroscopy analysis on the lower density sample in FIG. 4, it was learned that oxygen diffuses all the way down to the Cu surface. When oxygen diffuses to the Cu surface, the oxygen forms CuOₓ at the interface between Si—C—N—H and Cu. CuOₓ promotes electromigration because the Cu diffuses along this interface, if the adhesion between Cu and Si—C—N—H is poor due to CuOₓ layer. The solution for this problem illustrated in this example is to raise the deposition temperature and thereby increase the film density and barrier robustness. The downside to this process, other than a modest increase in dielectric constant, is the higher probability of Cu hillocks during deposition, which can lead to interlevel shorts.

### EXAMPLE 2

The specific 300 mm PECVD conditions for the optimized 350° C. process are 3 MS flow of 300 sccm, NH₃ flow of 1200 sccm, He flow of 1200 sccm, and RF plasma power of 640 watts. Films deposited under these processing conditions have similar film density to the 400° C. films described in Example 1, namely 2.15 g/cm³ by XRR. The dielectric constant of these films are slightly lower than the 400° C. films, namely 5.4, indicating that density is one of the determining factors in the dielectric constant value. Therefore, diffusion barrier effectiveness is proportional to both film density and dielectric constant.

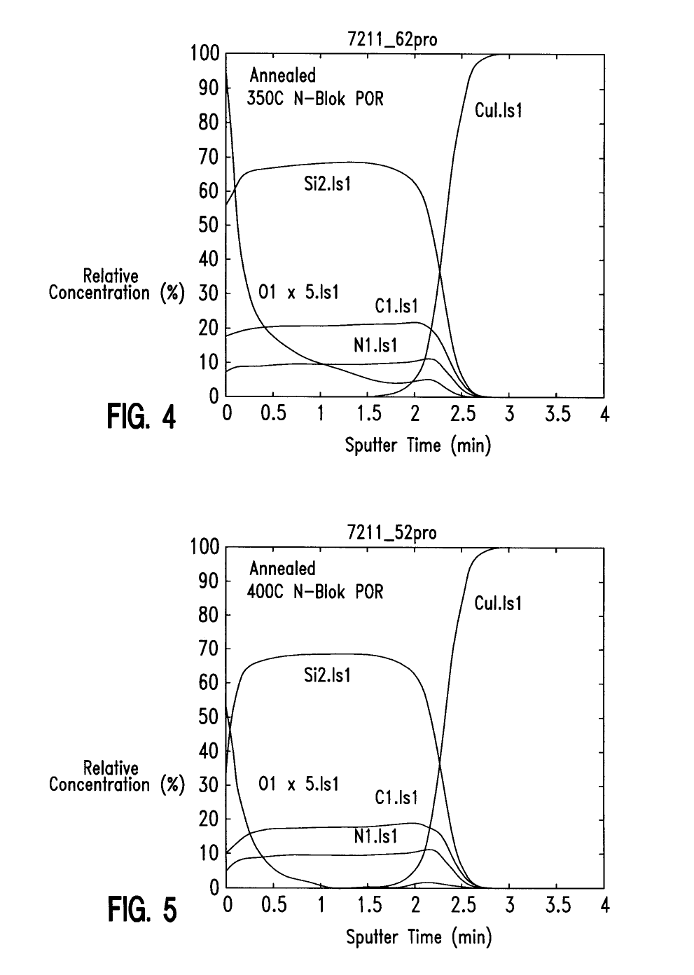

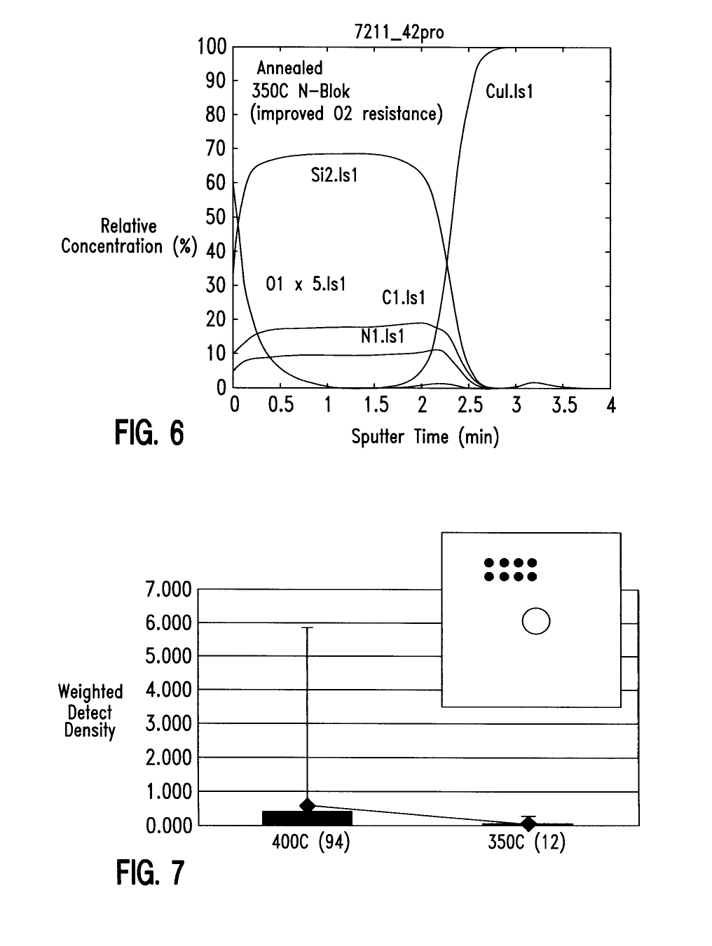

FIG. 6 shows the oxygen barrier property of this 350° C. film, by air annealing and AES depth profiling. Comparing FIG. 6 with FIG. 5 shows that the improved 350° C. processing conditions replicate both density and barrier effectiveness of the 400° C. film. By reducing the deposition temperature, the amount of hillocks occurring during deposition is reduced. This can be seen in FIG. 7, which depicts a comparison of weighted defect density of the 400° C. and optimized 350° C. processes, obtained by performing defect detection using darkfield wafer inspection. Decreasing the deposition temperature results in an 86% decrease in “embedded contamination” on the ILD material post-etch at the next processing level. Large Cu hillocks get blanketed with ILD at the next level, and appear to look like bumps or embedded foreign material directly over the previous level's Cu lines, depicted in the inset of FIG. 7.

Other benefits of reduced processing temperature include a reduced overall the thermal budget and by the nature of the Applied Materials Producer™ PECVD reactor, also an improved across-wafer uniformity. Additionally, perhaps due to the reduced number of hillocks, the electromigration is slightly improved compared to the 400° C. process.

1-13. (canceled)

14. A method for forming an interconnect structure on a substrate, the method comprising the steps of:
depositing at least one of an adhesion promoter layer and a transition layer on a substrate; depositing a dielectric material on the adhesion layer, thereby forming a dielectric layer;
depositing a sacrificial hardmask material on said dielectric layer, thereby forming a hardmask layer, said hardmask layer having a top surface which is removed; forming at least one opening in said hardmask and dielectric layers;
filling said opening with a conductive material, thereby forming at least one conductor, said conductor having a surface substantially coplanar with the top surface of said dielectric layer; and
depositing a cap layer on said conductor.

15. The method of claim 14 wherein said top surface is removed by CMP planarization.

16. The method of claim 14 wherein said cap material is selected from the group consisting of silicon, carbon, nitrogen and hydrogen.

17. The method of claim 16 wherein said cap layer is formed by a method comprising the steps of:
cleaning the substrate using a plasma cleaning process comprising heating the substrate to a temperature of about 150.degree. C. to about 500.degree. C. and exposing the substrate to a source of hydrogen for a time of about 5 to about 500 seconds; and
depositing the cap material using a plasma-enhanced chemical vapor deposition (PECVD) process which comprises placing the substrate into a reactor chamber at a temperature of about 150.degree. C. to about 500.degree. C. and at a pressure of about 0.1 torr to about 20 torr, exposing the substrate to at least one methyl silane compound, and applying RF power of about 100 watts to about 800 watts.
